(19) United States
(12) Patent Application Publication
(10) Pub. No.: US 2012/0018777 A1
(43) Pub. Date: Jan. 26, 2012

(54) THREE LEVEL POWER CONVERTING DEVICE

(75) Inventor: Satoki TAKIZAWA, Tokyo (JP)

(73) Assignee: FUJI ELECTRIC CO., LTD., Kawasaki-shi (JP)

(21) Appl. No.: 13/188,822

(22) Filed: Jul. 22, 2011

(30) Foreign Application Priority Data
Jul. 22, 2010 (JP) 2010-164738

(51) Int. Cl. H01L 29/739

(52) U.S. Cl. 257/140; 257/E29.197

(57) ABSTRACT

Aspects of the invention are directed to a three-level power converter that has, as one phase, a bidirectional switching element connected to the series connection point of a series circuit of a first insulated gate bi-polar transistor (“IGBT”) and second IGBT and an intermediate electrode of a direct current power supply. Also included is a fuse connected between the bidirectional switching element and the intermediate electrode of the direct current power supply, and an overcurrent shutdown unit provided in each gate drive circuit of the first and second IGBTs, are provided as protection from a power supply short circuit phenomenon occurring in the event of a short circuit failure of any of the IGBTs or diodes.

### BACKGROUND OF THE INVENTION

1. Technical Field

Embodiments of the present invention relate to an arm short circuit protection method of a three-level inverter or converter.

2. Related Art

A protection circuit wherein a fuse is used in a three-level converter is shown in Japanese Patent Publication No. JP-A-2004-248479 (see FIGS. 1 to 3). The three-level converter circuit shown here is a configuration that has, as one phase, a circuit wherein capacitors acting as a direct current power supply are connected in series, a positive electrode, an intermediate electrode, and a negative electrode act as direct current terminals, a series connection circuit of four IGBTs (two in an upper arm and two in a lower arm) to which diodes are connected in inverse parallel is connected between the positive electrode and negative electrode, and a diode for clamping the intermediate electrode is connected between the series connection point of the two upper arm insulated gate bipolar transistors (“IGBTs”) and the intermediate electrode of the direct current power supply, and between the series connection point of the two lower arm IGBTs and the intermediate electrode of the direct current power supply. The following three configurations 1 to 3 of an insertion position of a protective fuse in the circuit configuration are shown.

Configuration 1: Between the upper arm IGBTs and the positive electrode of the direct current power supply, and between the lower arm IGBTs and the negative electrode of the direct current power supply.

Configuration 2: Between the diode for clamping the intermediate electrode of the direct current power supply and the intermediate electrode of the direct current power supply, and between the upper arm IGBTs and the positive electrode of the direct current power supply.

Configuration 3: Between the diode for clamping the intermediate electrode of the direct current power supply and the intermediate electrode of the direct current power supply.

FIG. 6 shows a circuit configuration wherein the configuration 1 above is applied to a three-level power converting circuit (herein, a three phase inverter circuit) shown in Japanese Patent Publication No. JP-A-2008-193779 (see FIG. 3), on which the system is based. It is a configuration wherein three phases of a three-level IGBT module shown in FIG. 7 are connected in parallel between a positive electrode Pd and a negative electrode Nd of a direct current power supply circuit configured of a series circuit of capacitors C1 and C2 as a direct current power supply. As the circuit configuration of each phase is the same, a description will be given hereafter of a U-phase. The U-phase circuit is configured of a three-level IGBT module MJ1 in which is incorporated a series circuit of an IGBT T1 to which a diode D1 is connected in inverse parallel and an IGBT T2 to which a diode D2 is connected in inverse parallel, and a reverse parallel circuit of reverse blocking IGBTs T3 and T4 connected to the connection point of the emitter of the IGBT T1 and the collector of the IGBT T2, a fuse F1 connected between a terminal P of the IGBT module MJ1 and the positive electrode Pd of the direct current power supply, and a fuse F2 connected between a terminal N of the IGBT module MJ1 and the negative electrode Nd of the direct current power supply, wherein a terminal M of the IGBT module MJ1 is connected to an intermediate electrode Md of the direct current power supply. A V-phase circuit and W-phase circuit have the same configuration as the U-phase circuit. The alternating current output has the kind of three-level voltage waveform shown in FIG. 8, and a sinusoidal voltage with a small waveform distortion is supplied to a load LD via a filter reactor Lo, a filter capacitor, and the like.

A protective action in this kind of configuration will be described, centered on the U-phase.

In the case of the circuit type of FIG. 6, there are three paths along which a short circuit current flows when there is a semiconductor element short circuit failure. FIG. 9 shows a first short circuit path. The diagram shows a short circuit current path when the IGBT T3 is turned on in a condition in which there is a short circuit failure of the IGBT T1 or diode D1, or when the IGBT T1 is turned on in a condition in which there is a short circuit failure of the IGBT T3 or T4. In these cases, protection is possible by a voltage Edp of the upper side power supply C1 becoming the shorted path, and the fuse F1 in the path melting.

FIG. 10 shows a second short circuit path. The diagram shows a short circuit current path when the IGBT T4 is turned on in a condition in which there is a short circuit failure of the IGBT T2 or diode D2, or when the IGBT T2 is turned on in a condition in which there is a short circuit failure of the IGBT T3 or T4. In these cases, protection is possible by a voltage Edn of the lower side power supply C2 becoming the shorted path, and the fuse F2 in the path melting.

FIG. 11 shows a third short circuit path. The diagram is a current path diagram in a case occurring at a time of a two-level action using a switching of the T1 and T2, rather than at a time of a three-level action, when the IGBT T2 is turned on in a condition in which there is a short circuit failure of the IGBT T1 or diode D1, or when the IGBT T1 is turned on in a condition in which there is a short circuit failure of the IGBT T2 or diode D2. In these cases, protection is possible by a voltage which is the sum of the voltage Edp of the upper side power supply C1 and the voltage Edn of the lower side power supply C2 becoming the shorted path, and the fuse F1 and/or fuse F2 in the path melting.

FIG. 15 shows a one phase circuit with the above-described configuration 2 of Japanese Patent Publication No. JP-A-2004-248479 (see FIGS. 1 to 3). In the same way as with the above-described configuration 1, protection is possible by the fuse F1 and/or F3 melting when there is a failure of a semiconductor element short circuiting the upper side power supply C1, the fuse F3 melting when there is a failure of a semiconductor element short circuiting the lower side power supply C2, and the fuse F1 melting when the sum of the upper side power supply C1 and lower side power supply C2 is the shorted path.

Next, FIG. 16 shows a one phase circuit with the above-described configuration 3 of Japanese Patent Publication No. JP-A-2004-248479 (see FIGS. 1 to 3). Although protection is possible by the fuse F3 melting both when there is a failure of a semiconductor element short circuiting the upper side power supply C1 and when there is a failure of a semiconductor element short circuiting the lower side power supply C2, protection is not possible in a case of a short circuit failure occurring at a time of a two-level action using a switching of the T1 and T2.

FIGS. 12 and 13 show an example of an action at a time of a normal operation in the system in FIG. 6. The example shows a case in which the IGBT T1 is turned off (see FIG. 13) from a condition in which it is turned on (see FIG. 12).

When the IGBT T1 is turned off from a condition in which it is turned on (a condition in which a current flows along a path SC4 indicated by the dotted line), the IGBT T4 turned on in advance has continuity, and the current is commutated to a current path SC5. At that time, because the current in a path SC6 indicated by the dashed-dotted line decreases transiently, a voltage is generated in the directions of the arrows in the drawing, in accordance with a current change rate (di/dt) of the IGBT, in wire inductors LPM1 and LPM2 between the direct current power supply (C1 or C2) and the IGBT module.

As a result, a voltage is applied between the collector and emitter of the IGBT T1, to the maximum shown in Equation 1. FIG. 14 shows a collector current (ic) and a collector-emitter voltage (Vce) waveform when the IGBT T1 is turned off.

Vce(peak)=Edp+(LPM1+LPM2)·di/dt Equation 1

Surge voltage ΔV1=(LPM1+LPM2)·di/dt Equation 2

Edp: direct current voltage of direct current power supply 1

di/dt: current change rate of IGBT when IGBT is turned off

LPM1 and LPM2: inductance value of each wire

As one example, in the case of an IGBT in the several hundred amp class, as the maximum di/dt thereof is in the region of 5,000 A/μs, when LPM1+LPM2=100 nH, the surge amount ((LPM1+LPM2)·di/dt) according to Equation 1 is 500V.

Consequently, owing to the existence of the wire inductors LPM1 and LPM2, a peak voltage value applied to the IGBT when the IGBT is turned off is higher than the direct current voltage Edp by the amount of the surge voltage in Equation 2.

In general, by a main circuit conductor of a direct current portion being of a parallel flat plate structure (a laminated structure), any magnetic field generated is cancelled out, and a reduction in wiring inductance is achieved, but when connecting a fuse as in the system of FIG. 6, a parallel flat plate structure cannot be adopted in that place, and it is not possible to achieve a reduction in wiring inductance.

Also, as fuses are used in two places in the configuration shown in FIG. 15 too, the wiring inductance increases in the same way.

When connecting a fuse as heretofore described, a high surge voltage is generated when switching due to an increase in inductance, the application of a module with a high withstand voltage, the connection of a snubber circuit, or the like, is necessary, and problems occur in that there is an increase in size and a rise in price of the device. In the case of a three-level inverter in particular, as it is necessary to connect fuses in two places, these problems are notable.

Also, in the circuit configuration shown in FIG. 16, protection is not possible for a two-level action.

### SUMMARY OF THE INVENTION

Consequently, an object of embodiments of the invention is to provide a protection circuit that realizes a reliable protective action, while reducing wiring inductance to an extreme, and keeping surge voltage small at a time of a switching.

In order to achieve this and/or other objects, in a first aspect of the invention, a three-level power converting device, which is a voltage type three-level power converter that has, as one phase, a direct current power supply, configured with two direct current power supplies connected in series and having a positive electrode, an intermediate electrode, and a negative electrode, a first IGBT whose collector is connected to the positive electrode of the direct current circuit and to which a diode is connected in inverse parallel, a second IGBT whose emitter is connected to the negative electrode of the direct current circuit and to which a diode is connected in inverse parallel, and a bidirectional switching element configured of a third IGBT and fourth IGBT, connected in inverse parallel, connected to the connection point of the emitter of the first IGBT and collector of the second IGBT and the intermediate electrode of the direct current power supply, includes an overcurrent protection function that protects the device from a power supply short circuit phenomenon occurring in the event of a short circuit failure of any of the IGBTs or diodes, a fuse connected between the bidirectional switching element and the intermediate electrode of the direct current power supply, and an overcurrent shutdown unit provided in each gate drive circuit of the first and second IGBTs.

In a second aspect of the invention, the fuse according to the first aspect of the invention is used for all of a plurality of phases of the three-level power converter.

In a third aspect of the invention, the overcurrent shutdown unit according to the first aspect of the invention monitors a collector-emitter turn-on voltage of the first or second IGBT, determines that there is an overcurrent when the turn-on voltage rises to or above a predetermined value, and shuts off a gate signal.

In a fourth aspect of the invention, IGBTs with a current sense terminal for detecting current are used as the first and second IGBTs according to the first aspect of the invention, and the overcurrent shutdown unit detects an overcurrent with the current sense terminal, and shuts off a gate signal.

In a fifth aspect of the invention, the overcurrent shutdown unit according to the first aspect of the invention detects an overcurrent of the collector or emitter of the first or second IGBT with a current detector, and shuts off a gate signal.

In embodiments of the invention, the protective fuses used are used one in each phase or one for a plurality of phases, and the overcurrent shutdown function is incorporated in the gate drive circuit of the first and second IGBTs.

As a result, wiring inductance decreases, it is possible to suppress the surge voltage when switching, and it is possible to realize a reliable protection function.

### BRIEF DESCRIPTION OF THE DRAWINGS

FIG. 1 is a circuit diagram showing a first working example of embodiments of the invention;

FIG. 2 is a circuit diagram showing a second working example of embodiments of the invention;

FIG. 3 is a circuit diagram showing a third working example of embodiments of the invention;

FIG. 4 is a circuit diagram showing a fourth working example of embodiments of the invention;

FIG. 5 is a circuit diagram showing a fifth working example of embodiments of the invention;

FIG. 6 is a circuit diagram showing a heretofore known first working example;

FIG. 7 shows an external appearance of a three-level IGBT module;

FIG. 8 is an example of an output voltage waveform of a three-level inverter;

FIG. 9 shows a first path of a short circuit current of FIG. 6;

FIG. 10 shows a second path of a short circuit current of FIG. 6;

FIG. 11 shows a third path of a short circuit current of FIG. 6;

FIG. 12 shows a current path and wire inductors at a time of a normal action of FIG. 6;

FIG. 13 shows a current path and a wire inductor induction voltage at a time of a commutation of FIG. 6;

FIG. 14 shows an example of a voltage-current waveform of an IGBT when switching;

FIG. 15 shows a heretofore known second working example; and

FIG. 16 shows a heretofore known third working example.

### DETAILED DESCRIPTION

By way of embodiments of the invention, in a voltage type three-level power converter that has, as one phase, a direct current power supply, configured with two direct current power supplies connected in series and having a positive electrode, an intermediate electrode, and a negative electrode, a first IGBT whose collector is connected to the positive electrode of the direct current circuit and to which a diode is connected in inverse parallel, a second IGBT whose emitter is connected to the negative electrode of the direct current circuit and to which a diode is connected in inverse parallel, and a bidirectional switching element configured of a third IGBT and fourth IGBT, connected in inverse parallel, connected to the connection point of the emitter of the first IGBT and collector of the second IGBT and the intermediate electrode of the direct current power supply, a fuse connected between the bidirectional switching element and the intermediate electrode of the direct current power supply, and an overcurrent shutdown circuit in each gate drive circuit of the first and second IGBTs, are provided as an overcurrent protection function that protects the device from a power supply short circuit phenomenon at a time of a semiconductor element short circuit failure.

### Working Example 1

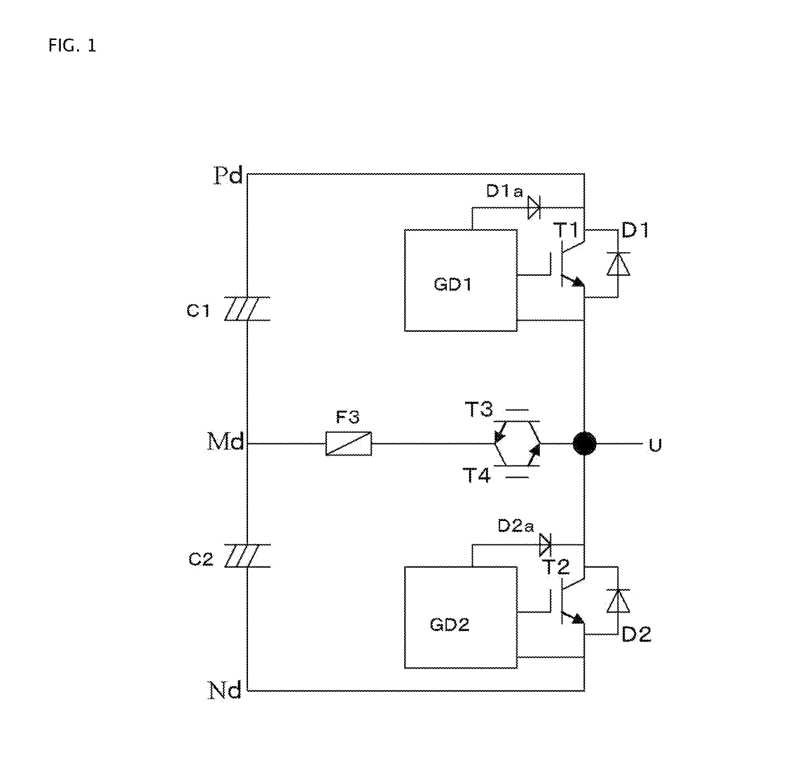

A first working example of embodiments of the invention is shown in FIG. 1. It is a circuit configuration of a voltage type three-level power converter that has, as one phase, a direct current power supply, configured with two capacitors C1 and C2 connected in series as a direct current power supply and having a positive electrode, an intermediate electrode, and a negative electrode, a first IGBT T1 whose collector is connected to the positive electrode of the direct current circuit and to which a diode D1 is connected in inverse parallel, a second IGBT T2 whose emitter is connected to the negative electrode of the direct current circuit and to which a diode D2 is connected in inverse parallel, and a bidirectional switching element configured of a third IGBT T3 and fourth IGBT T4, connected in inverse parallel, connected to the connection point of the emitter of the first IGBT T1 and collector of the second IGBT T2 and the intermediate electrode of the direct current power supply. Although a one phase circuit is shown in the drawing, a single phase converting device or three phase converting device is configured by connecting a plurality of the circuits in parallel.

A fuse connected between the bidirectional switching element and the intermediate electrode of the direct current power supply, and an overcurrent shutdown circuit in each gate drive circuit of the first and second IGBTs, are provided as an overcurrent protection function that protects a device from a power supply short circuit phenomenon at a time of a semiconductor element short circuit failure. Herein, a gate drive circuit GD1 and diode D1a connected to the first IGBT T1, and a gate drive circuit GD2 and diode D2a connected to the second IGBT T2, are each configurations including an overcurrent shutdown circuit. The principle of overcurrent shutdown is that a turn-on voltage of the IGBTs T1 and T2 is detected by the diodes D1a and D2a and, utilizing the fact that the voltage rises when there is an overcurrent, an on signal in the gate drive circuits GD1 and GD2 is shut off. Although a collector-emitter voltage Vice of the IGBT is in the region of a few volts for the duration of the on signal, as it increases to several tens of volts or more in the event of an overcurrent, this is detected using the diodes D1a and D2a, and the gate on signal is shut off. As this overcurrent shutoff circuit is heretofore known from Japanese Patent Document JP-A-5-161342, and the like, a detailed description will be omitted.

With this kind of configuration, in a first short circuit current path, which is a short circuit current path when the IGBT T3 is turned on in a condition in which there is a short circuit failure of the IGBT T1 or diode D1, or when the IGBT T1 is turned on in a condition in which there is a short circuit failure of the IGBT T3 or T4, protection is possible by the upper side power supply C1 becoming the shorted path, and a fuse F3 in the path melting. Also, in a second short circuit current path, which is a short circuit current path when the IGBT T4 is turned on in a condition in which there is a short circuit failure of the IGBT T2 or diode D2, or when the IGBT T2 is turned on in a condition in which there is a short circuit failure of the IGBT T3 or T4, protection is possible by the voltage of the lower side power supply C2 becoming the shorted path, and the fuse F3 in the path melting.

Next, a description will be given of an action at a time of a two-level action using a switching of the IGBTs T1 and T2, rather than at a time of a three-level action. A current path when the IGBT T2 is turned on in a condition in which there is a short circuit failure of the IGBT T1 or diode D1, and when the IGBT T1 is turned on in a condition in which there is a short circuit failure of the IGBT T2 or diode D2, is a path wherein a power supply which is the sum of the upper side power supply C1 and lower side power supply C2 is short circuited, at which time, the normal IGBT T1 or T2 is protected by detecting and shutting down the overcurrent. When there is an action of this kind of overcurrent protection circuit, such as a fuse melting or an overcurrent shutdown, notification of the action is transmitted to an unshown control circuit as a failure signal, and the whole of the device is stopped, meaning that protection of the whole of the device is realized.

### Working Example 2

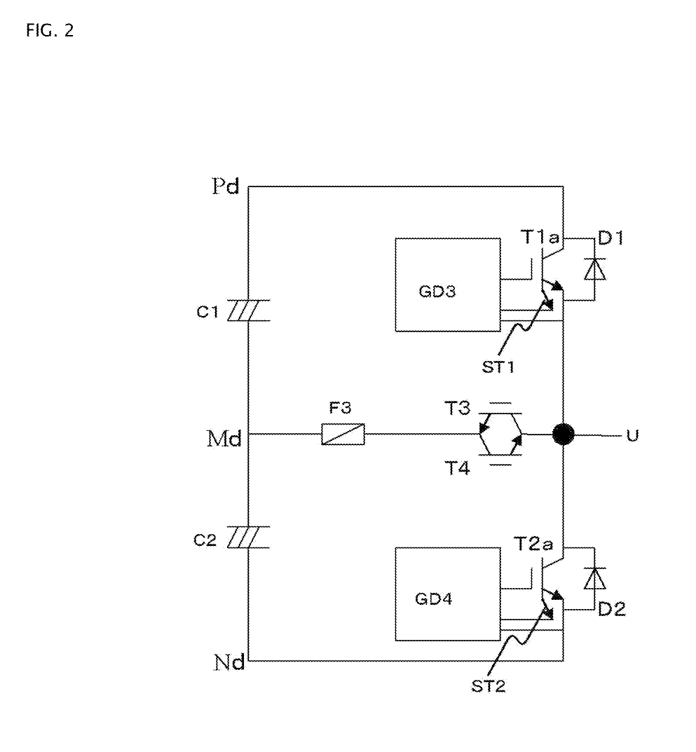

FIG. 2 shows a second working example of embodiments of the invention. The difference from the first working example is in the point that IGBTs with a current sense terminal for detecting current are used as IGBTs T1a and T2a, and the overcurrent shutdown unit detects an overcurrent with the current sense terminal, and shuts off the gate signal. As this overcurrent protection method is heretofore known from JP-A-4-79758, and the like, a detailed description will be omitted. With this kind of configuration too, in the same way as in the first working example, it is possible to realize protection of each overcurrent path.

### Working Example 3

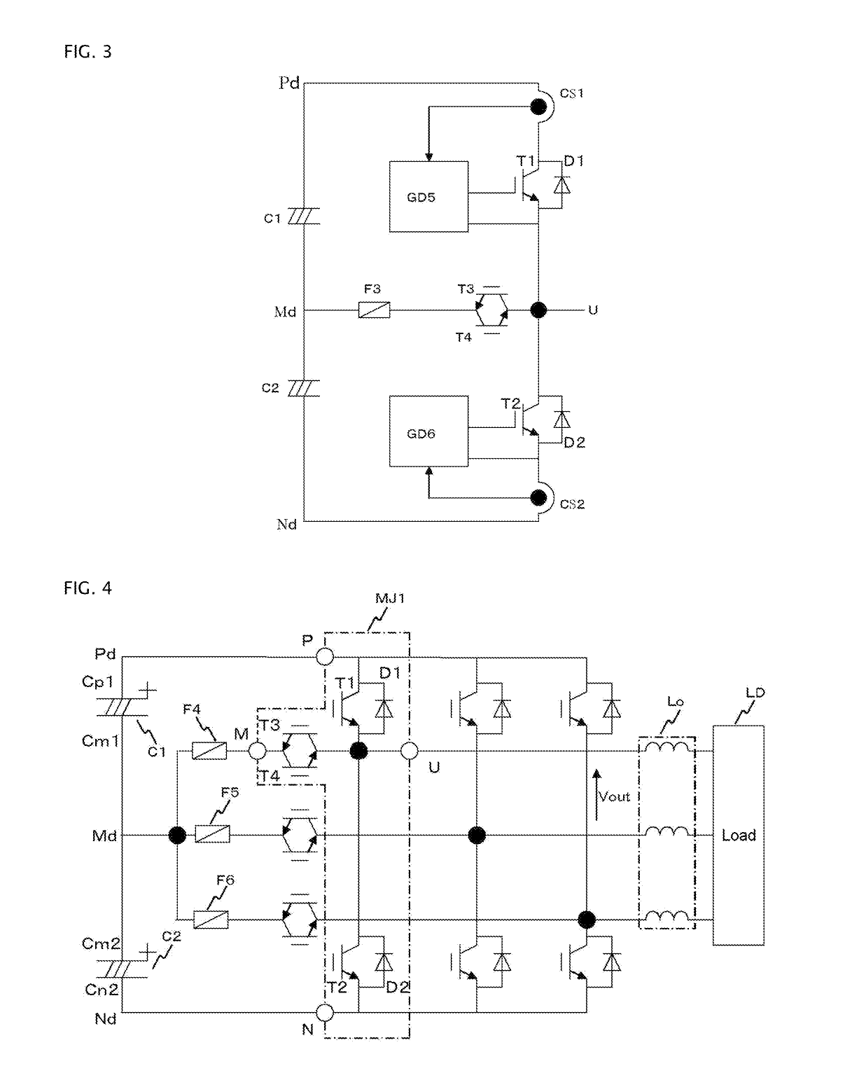

FIG. 3 shows a third working example of embodiments of the invention. The difference from the first and second working examples is in the point that current detectors CS1 and CS2, such as a hole CT, are used for overcurrent detection. When an overcurrent is detected, the on signal of the gate drive circuit is shut off. With this kind of configuration too, in the same way as in the first and second working examples, it is possible to realize protection of each overcurrent path.

### Working Example 4

FIG. 4 shows a fourth working example of embodiments of the invention.

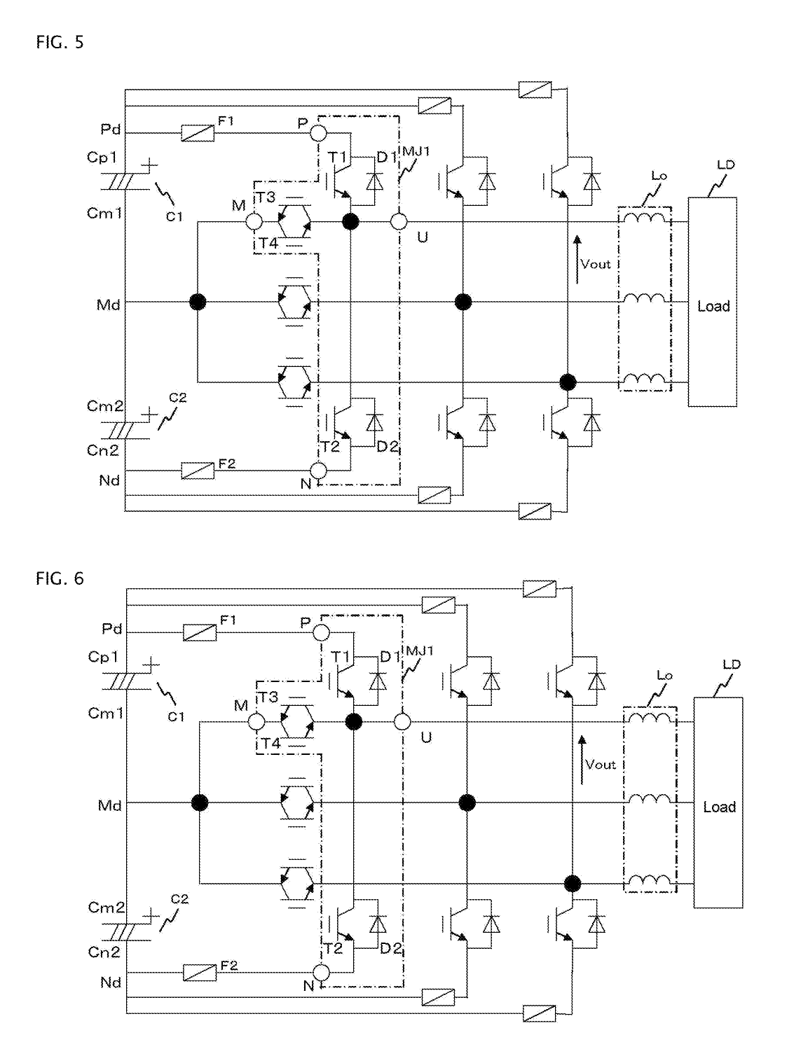

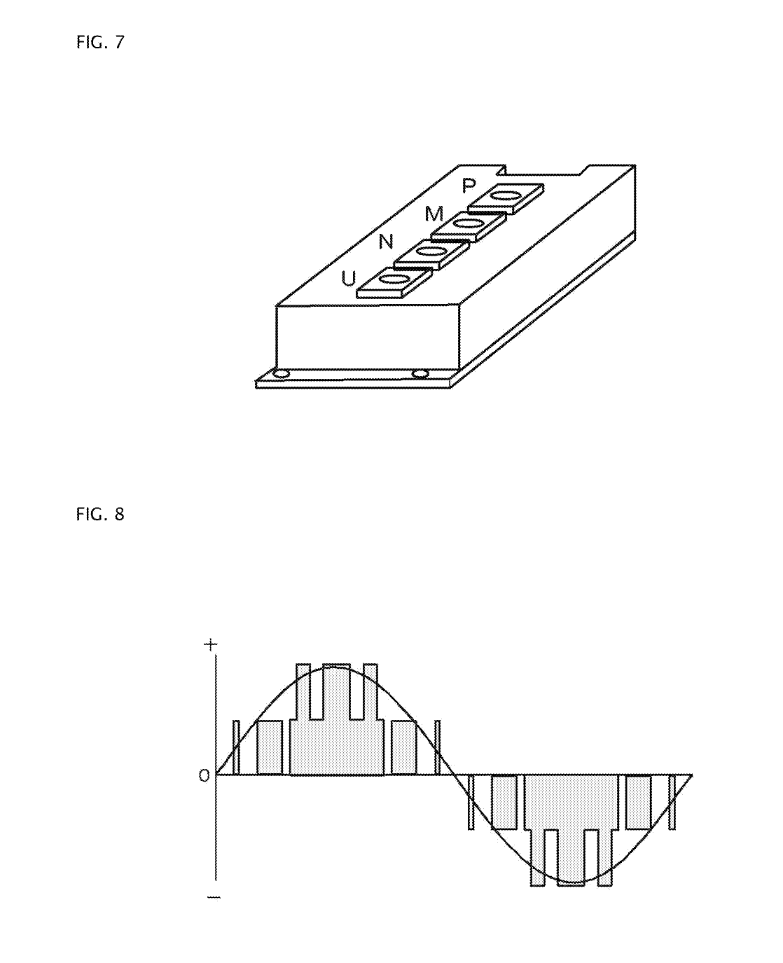

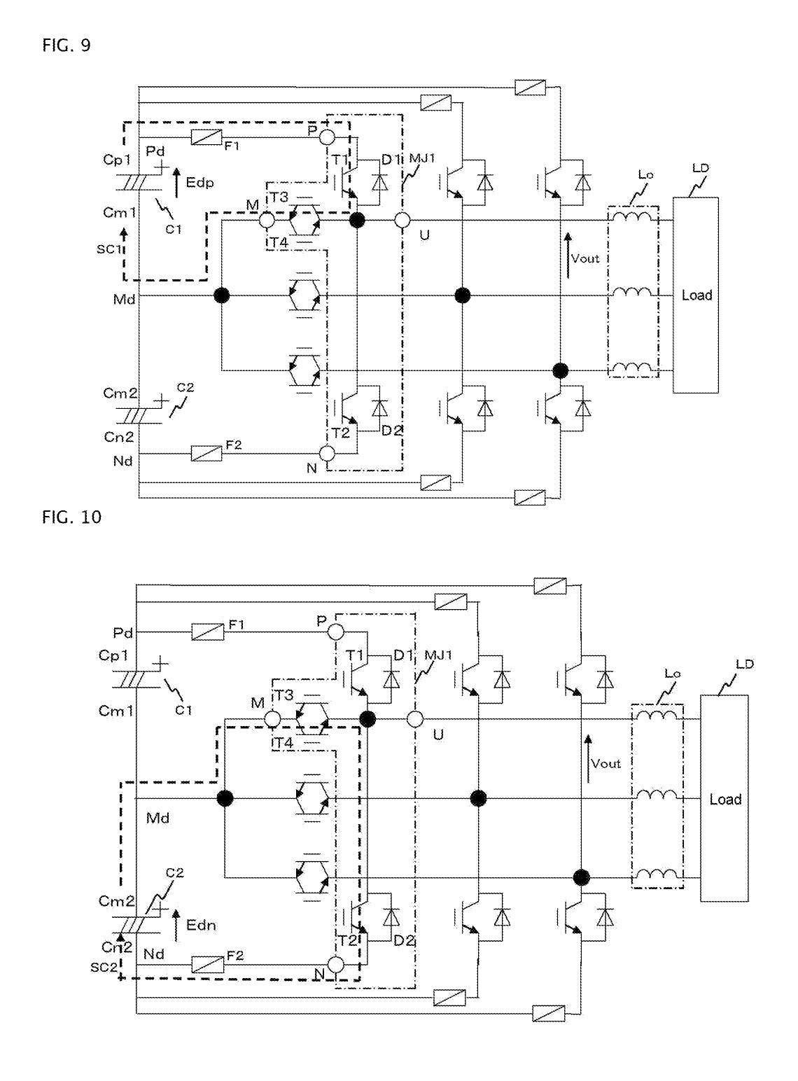

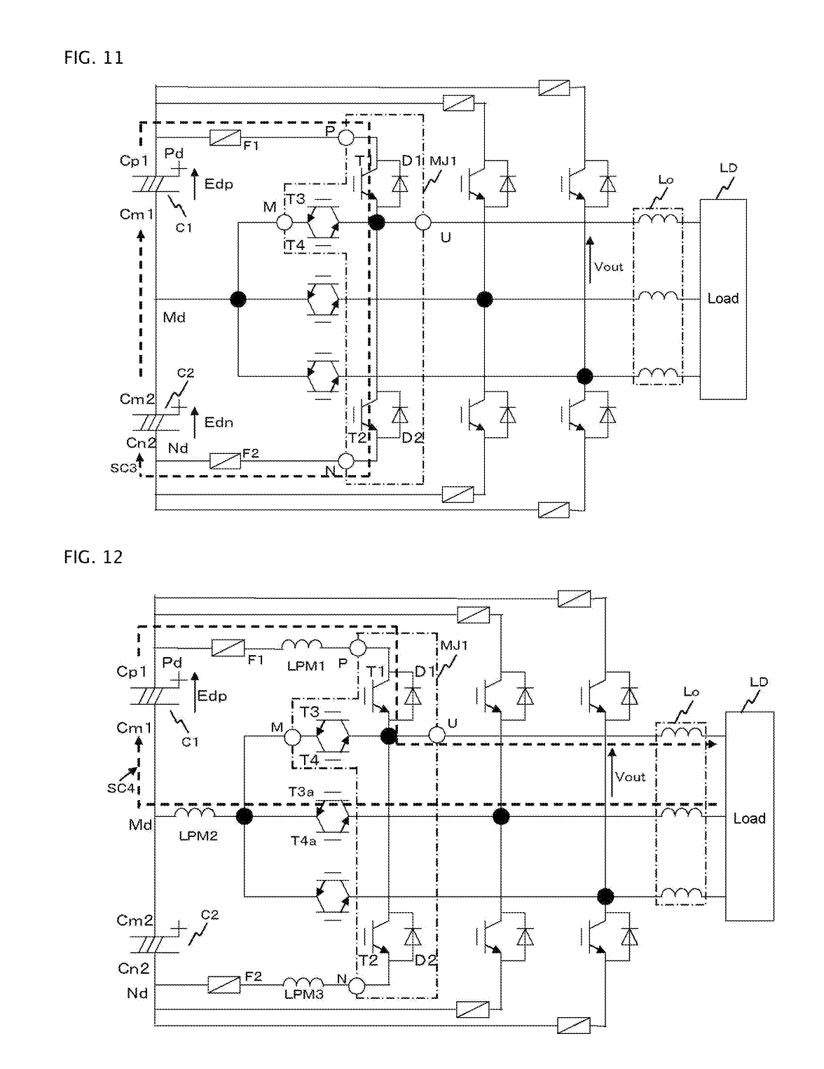

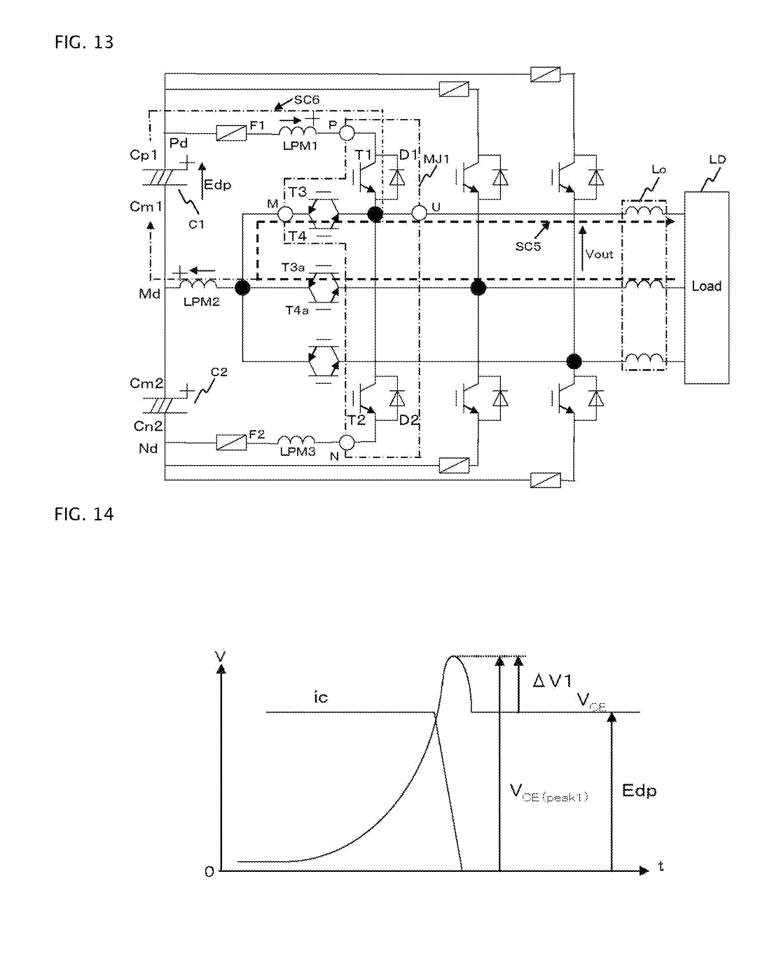

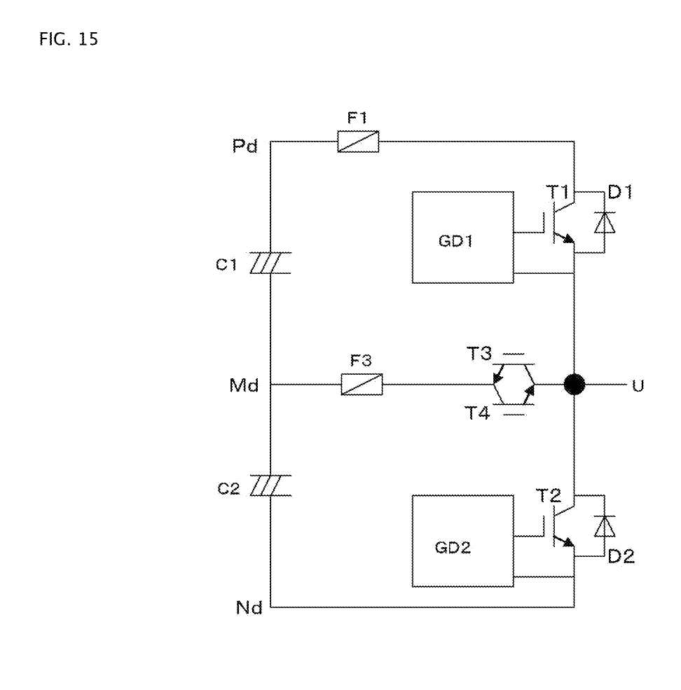

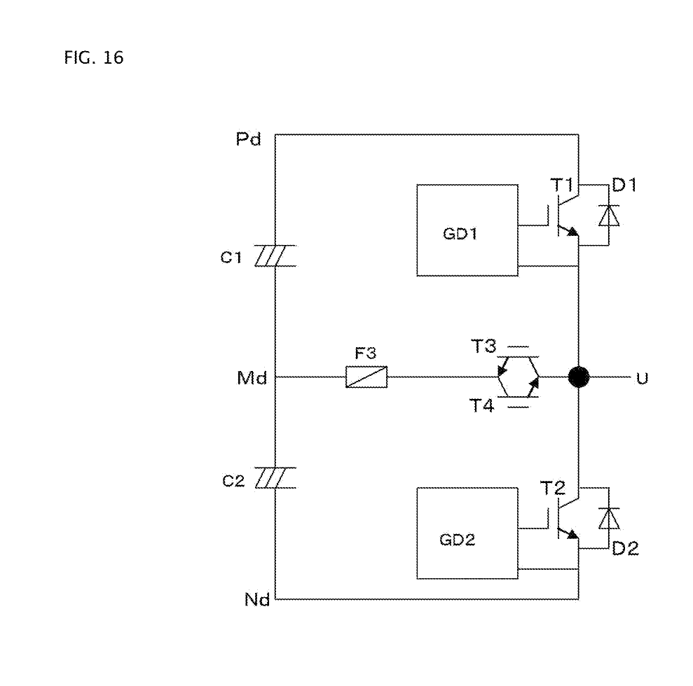

In the first to third working examples, a description has been given of an example of a configuration of one phase each, but this working example relates to a method of inserting a fuse in a single phase full-bridge circuit, a three phase open delta connection bridge circuit, a three phase full-bridge circuit, or the like, configured of a plurality of phases. FIG. 5 is a configuration wherein one each of fuses F4 to F6 is inserted in each phase of a three phase inverter circuit, but FIG. 4 is a working example wherein the one fuse F3 is inserted for the three phases together. When a short circuit failure occurs in any of the IGBTs T1 and T2, the diodes D1 and D2, or the reverse blocking IGBTs T3 and T4 in any of the three phases, the fuse F3 is shut off, and the circuit is protected. In a two-level action, protection can be realized in the same way by incorporating an overcurrent protection circuit in the gate drive circuits of the IGBT T1 and IGBT T2, in the same way as in the first to third working examples. As it is sufficient to use one fuse, the protection is effective in a small capacity device in which wiring inductance does not increase even when three phases are brought together.

In the working examples, an example has been given of a three phase three-level converting device, but the protection can also be realized in a single phase half-bridge circuit, a single phase full-bridge circuit, a three phase full-bridge circuit, an open delta connection circuit, or the like.

Embodiments of the invention are directed to the protection of a three-level AC-DC converting circuit or DC-AC converting circuit, and can be applied to a direct current power supply device, an alternating current power supply device, an uninterruptible power supply (UPS) device, a motor drive device, or the like.

Examples of specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the above description, specific details are set forth in order to provide a thorough understanding of embodiments of the invention. Embodiments of the invention may be practiced without some or all of these specific details. Further, portions of different embodiments can be combined, as would be understood by one of skill in the art.

This application is based on, and claims priority to, Japanese Patent Application No. 2010-164738, filed on Jul. 22, 2010. The disclosure of the priority application, in its entirety, including the drawings, claims, and the specification thereof, is incorporated herein by reference.

What is claimed is:

1. A three-level power converting device, which is a voltage type three-level power converter that has, as one phase, a direct current power supply, configured with two direct current power supplies connected in series and having a positive electrode, an intermediate electrode, and a negative electrode, a first IGBT whose collector is connected to the positive electrode of the direct current circuit and to which a diode is connected in inverse parallel, a second IGBT whose emitter is connected to the negative electrode of the direct current circuit and to which a diode is connected in inverse parallel, and a bidirectional switching element configured of a third IGBT and fourth IGBT, connected in inverse parallel, connected to the connection point of the emitter of the first IGBT and collector of the second IGBT and the intermediate electrode of the direct current power supply,
the device comprising:
an overcurrent protection function that protects the device from a power supply short circuit phenomenon occurring in the event of a short circuit failure of any of the IGBTs or diodes;
a fuse connected between the bidirectional switching element and the intermediate electrode of the direct current power supply; and
an overcurrent shutdown unit provided in each gate drive circuit of the first and second IGBTs.

2. The three-level power converting device according to claim 1, wherein
the fuse is used for all of a plurality of phases of the three-level power converter.

3. The three-level power converting device according to claim 1, wherein
the overcurrent shutdown unit monitors a collector-emitter turn-on voltage of the first or second IGBT, determines that there is an overcurrent when the turn-on voltage rises to or above a predetermined value, and shuts off a gate signal.

4. The three-level power converting device according to claim 1, wherein
IGBTs with a current sense terminal for detecting current are used as the first and second IGBTs, and the overcurrent shutdown unit detects an overcurrent with the current sense terminal, and shuts off a gate signal.

5. The three-level power converting device according to claim 1, wherein
the overcurrent shutdown unit detects an overcurrent of the collector or emitter of the first or second IGBT with a current detector, and shuts off a gate signal.
